(19) United States
(12) Patent Application Publication
(10) Pub. No.: US 2009/0079514 A1
(43) Pub. Date: Mar. 26, 2009

(54) HYBRID ACOUSTIC RESONATOR-BASED FILTERS

(76) Inventors: Tiberiu Jamneala, San Francisco, CA (US); Martha Small, Fort Collins, CO (US); Richard C. Ruby, Menlo Park, CA (US)

Correspondence Address: Kathy Manke;Avago Technologies Limited, 4380 Ziegler Road, Fort Collins, CO, 80525, US

(21) Appl. No.: 11/860,107

(22) Filed: Sep. 24, 2007

(51) Int. Cl. H03H 9/70; H03H 9/58

(52) U.S. Cl. 333/133; 333/189

(57) ABSTRACT

A hybrid acoustic resonator filter and a communication device with a hybrid acoustic resonator filter is described.

### BACKGROUND

In many different communications applications, a common signal path is coupled both to the input of a receiver and to the output of a transmitter. For example, in a transceiver, such as a cellular or cordless telephone, an antenna may be coupled to the input of the receiver and to the output of the transmitter. In such an arrangement, a duplexer is used to couple the common signal path to the input of the receiver and to the output of the transmitter. The duplexer provides the necessary coupling while preventing the modulated transmit signal generated by the transmitter from being coupled from the antenna back to the input of the receiver and overloading the receiver.

Often, among other elements, filters are used to prevent the undesired coupling of these signals. One type of filter is based on a film bulk acoustic resonator (FBAR) structure. The FBAR includes an acoustic stack comprising, inter alia, a layer of piezoelectric material disposed between two electrodes. Acoustic waves achieve resonance across the acoustic stack, with the resonant frequency of the waves being determined by the materials in the acoustic stack.

FBARs are similar in principle to bulk acoustic resonators such as quartz, but are scaled down to resonate at GHz frequencies. Because the FBARs have thicknesses on the order of microns and length and width dimensions of hundreds of microns, FBARs beneficially provide a comparatively compact alternative to known resonators.

FBAR filters are often configured in a lattice or ladder filter arrangements, with a basic building block being a pair of resonators with slightly different resonation frequencies. A half-ladder filter comprises a pair of resonators topologically arranged with one series resonator and one shunt resonator. These filters are often referred to as containing electrically coupled resonators. Among other benefits, through proper tuning the FBARs and properly selecting the number of stages of half-ladder elements, the passband of the electrically coupled FBAR filters can be selected with precision. Moreover, the passband rolloff (and thus nearband rejection) can be made comparatively sharp, which is useful in preventing overlap of the transmission and reception bands in a duplex or multiplex application.

While providing clear benefits in size and performance, FBAR filters are not adapted for single-ended (balanced) to differential (unbalanced) signal transformation. More and more there is a need for such differential signal applications from a single ended input. This has led to the investigation of alternative filter arrangements.

One way of providing a single-ended to differential signal transformation in a filter application involves a device known as a balun. For example, the balun may be connected to an FBAR-based filter. Unfortunately, and among other drawbacks, the use of a balun adds another (external) element to circuit, driving up the cost, size and insertion loss of the filter.

While acoustic resonators operative to provide single-ended to differential output filtering without a balun are known, these known devices suffer from an unacceptably weak nearband rejection. As such, their use in many applications, such as in full-duplex communications is not practical.

There is a need, therefore, for a single-ended to differential filter that overcomes at least the shortcoming of known filters discussed above.

### SUMMARY

In a representative embodiment, a hybrid acoustic resonator filter adapted for single-ended to differential signal transformation comprises: a film bulk acoustic resonator (FBAR) filter section comprising a single-ended output; and a coupled mode resonator filter (CRF) section comprising an input connected to the single-ended output, and a differential signal output.

In another representative embodiment, a communication device comprises: a transmitter; a receiver; and a hybrid acoustic resonator filter adapted for single-ended to differential signal transformation. The hybrid acoustic resonator filter comprises: a film bulk acoustic resonator (FBAR) filter section comprising a single-ended output; and a coupled mode resonator filter (CRF) section comprising an input connected to the single-ended output, and a differential signal output.

In another representative embodiment, a hybrid acoustic resonator filter adapted for single-ended to differential signal transformation, comprises: an electrically coupled film bulk acoustic wave resonator (FBAR) filter section having a single-ended signal output; and an acoustically coupled film bulk acoustic wave resonator filter section connected to the single-ended signal output and comprising a differential signal output.

In another representative embodiment, a communication device comprises: a transmitter; a receiver; and a hybrid acoustic resonator filter adapted for single-ended to differential signal transformation. The hybrid acoustic resonator filter comprises: an electrically coupled film bulk acoustic wave resonator (FBAR) filter section having a single-ended signal output; and an acoustically coupled film bulk acoustic wave resonator filter section connected to the single-ended signal output and comprising a differential signal output.

### BRIEF DESCRIPTION OF THE DRAWINGS

The present teachings are best understood from the following detailed description when read with the accompanying drawing figures. The features are not necessarily drawn to scale. Wherever practical, like reference numerals refer to like features.

FIG. 1 is a cross-sectional view of a hybrid acoustic resonator filter in accordance with a representative embodiment.

FIG. 2 is a cross-sectional view showing a hybrid acoustic resonator filter during fabrication in accordance with representative embodiment.

FIG. 3 is a cross-sectional view of a hybrid acoustic resonator filter in accordance with a representative embodiment.

FIG. 4 is a simplified schematic view of a communication device in accordance with a representative embodiment.

FIG. 5 is a graphical representation of a passband of a known coupled mode resonator filter.

FIG. 6 is a graphical representation of a passband of a hybrid acoustic resonator filter in accordance with representative embodiment.

### DEFINED TERMINOLOGY

As used herein, the terms ‘a’ or ‘an’, as used herein are defined as one or more than one.

As used herein, the term “hybrid acoustic resonator filter” is defined as a single-ended electrically coupled acoustic resonator filter section connected to an acoustically coupled acoustic resonator filter section adapted to provide single-ended to differential signal transformation.

### DETAILED DESCRIPTION

In the following detailed description, for purposes of explanation and not limitation, representative embodiments disclosing specific details are set forth in order to provide a thorough understanding of the present teachings. Descriptions of known devices, materials and manufacturing methods may be omitted so as to avoid obscuring the description of the example embodiments. Nonetheless, such devices, materials and methods that are within the purview of one of ordinary skill in the art may be used in accordance with the representative embodiments.

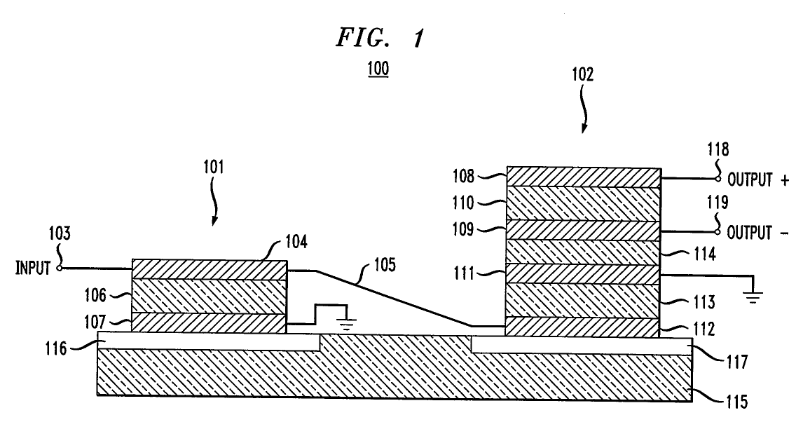

FIG. 1 is a cross-sectional view of a hybrid acoustic resonator filter 100 in accordance with a representative embodiment. The filter 100 comprises an FBAR filter section 101 and a coupled resonator filter (CRF) section 102. The FBAR filter section 101 has an input 103 connected to an upper electrode 104 and an output 105 connected to the CRF section 102. A piezoelectric layer 106 is disposed between the upper electrode 104 and a lower electrode 107, which is connected to ground in the representative embodiment.

The CRF section 102 comprises an upper FBAR comprising an upper electrode 108, a lower electrode 109 and a piezoelectric layer 110 disposed therebetween. The CRF section 102 further comprises a lower FBAR comprising an upper electrode 111, a lower electrode 112 and a layer of piezoelectric material 113 disposed therebetween. The CRF comprises an acoustic decoupling layer 114 disposed between the first and second electrodes FBARs, and particularly between the upper electrode 111 of the second FBAR and the lower electrode 107 of the first FBAR. The CRF section 102 may be one of a number of topologies known to those skilled in the art. For instance, the CRF section 102 may be as described in one or more of the following commonly owned U.S. Pat. Nos. 7,019,605 to Bradley, et al.; and 6,946,928 to Larson, et al.; and one or more of the following commonly owned U.S. Patent Publications: 20050093658 to Larson, et al; 20050093655 to Larson, et al.; and 20070176710 to Jamneala, et al. The disclosure of these patents and patent publications are specifically incorporated herein by reference. More generally, the CRF section 102 may be an acoustically coupled filter adapted for single-ended to differential signal transformation and amenable to manufacturing in parallel to or in sequence with the FBAR filter section 101.

In certain embodiments, FBAR filter section 101 may be a single stage FBAR filter, while in other embodiments FBAR filter section 101 may be a multi-stage FBAR filter in order to provide suitable nearband rejection. Notably, the FBAR filter section 101 may comprise a half-ladder FBARs (i.e., series and a shunt FBARs), or a plurality of half-ladders, with the terminus half-ladder being connected to the CRF via output 105. As will be appreciated by one of ordinary skill in the art, additional stages selectively tuned provide nulls in the passband to effect the desired nearband rejection. Accordingly, multi-stage FBAR filter sections are contemplated for use as the electrically coupled acoustic filters of the hybrid acoustic resonator filter of the representative embodiments. It is emphasized that the FBAR topologies implemented to form the FBAR filter section 101 are intended merely to be illustrative. Further details of ladder filters may be found, for example, in commonly assigned U.S. Pat. No. 6,626,637, entitled “Duplexer Incorporating thin-film bulk acoustic resonators (FBARs)” to Bradley, et al. The disclosure of this patent is specifically incorporated herein by reference.

Other topologies are contemplated for the FBAR filter section 101, however. Some alternative single-ended filter sections are described more fully herein, while others within the purview of one of ordinary skill in the art are also contemplated. Notably, the FBAR filter section 101 having a single-ended output (termination) is contemplated to comprise selective combinations of FBAR filters, SBAR filters and CRFs. In general, electrically coupled filter sections with single-ended termination, which provide the desired passband/rejection characteristics for duplex communications, and which are amenable to manufacturing in parallel or in sequence with the CRF section 102 are contemplated. As the noted filter topologies for FBAR section 101 are known to those skilled in the art, details are generally omitted in order to avoid obscuring the description of the representative embodiments.

As shown in FIG. 1, the FBAR filter section 101 and the CFR section 102 are provided over a common substrate 115 with a cavity or reflector (e.g., an acoustic Bragg reflector or similar acoustic mirror), 116 and 117, respectively, disposed therebetween. The need for, and manufacturing and function of the cavities/reflectors 116, 117 are well known. For example, the reflector(s) may be a mismatched acoustic Bragg reflector formed in or on the substrate 115, as disclosed in U.S. Pat. No. 6,107,721 to Lakin, the disclosure of which is specifically incorporated into this disclosure by reference in its entirety. Moreover, the cavities 116, 117 may be fabricated according to known semiconductor processing methods and using known materials. Illustratively, the cavities 116,117 may be fabricated according to the teachings of U.S. Pat. Nos. 5,587,620, 5,873,153 and 6,507,583 to Ruby, et al. The disclosures of these patents are specifically incorporated herein by reference. It is emphasized that the methods described in these patents are representative and other methods of fabrication and materials within the purview of one of ordinary skill in the art are contemplated.

Furthermore, the upper electrodes 104, 108,111 and lower electrodes 107, 109, 112 may be selectively apodized and may include mass loading layers. The use of apodization and mass loading are known to those of ordinary skill in the art and details thereof are generally omitted in order to avoid obscuring the description of the representative embodiments. For example, details of apodization may be found in U.S. patent application Ser. No. 11/443,954, entitled “Piezoelectric Resonator Structures and Electrical Filters” to Richard C. Ruby, et al. In addition, details of mass loading may be found in U.S. patent application Ser. No. 10/990,201, entitled “Thin Film Bulk Acoustic Resonator with Mass Loaded Perimeter” to Hongjun Feng, et al.; and U.S. patent application Ser. No. 11/713,726, entitled “Piezoelectric Resonator Structures and Electrical Filters having Frame Elements” to Jamneala, et al.

Operation of the filter 100 is described presently, and in connection with other embodiments herein. As will be appreciated by one of ordinary skill in the art, and as will become clearer as the present description continues, terms ‘input’ and ‘output’ are interchangeable depending on the signal direction. Moreover, the sign convention of the voltages (+/−) shown is merely illustrative and of course, depends on the piezoelectric materials selected for the filter sections (e.g., the direction of the c-axes) and the selected ground connections.

A signal is provided at the input 103, which is connected to the upper electrode 104 of the FBAR filter section 101. The filtered signal is provided to output 105, which is input to the lower electrode 112 of the CRF section 102. The CRF section 102 provides a differential output, with a positive output 118, and a negative output 119. The upper electrode 111 is maintained at ground as shown. Accordingly, a single-ended signal is input at the FBAR filter section 101 and is transformed to a differential signal at the output of the CRF section 102. Naturally, input of a differential signal to the ‘outputs’ 118, 119 provides a filtered single-ended signal at the ‘input’ 103.

Beneficially, and as described more fully herein, the hybrid acoustic resonator filter 100 provides, among other things, the desired near-band rejection of an electrically coupled filter section (e.g., FBAR filter section) with the differential signal performance of an acoustically coupled resonator (e.g., CRF). Moreover, because an external balun is avoided and because the filters can be fabricated in the same processing sequence with insignificant variation, a reduction in filter size and cost can be realized.

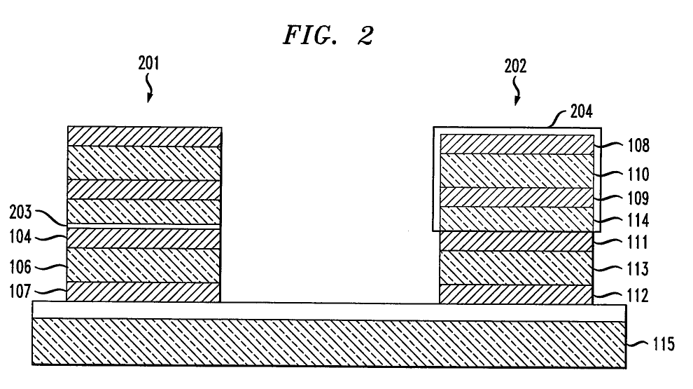

Fabrication of the filter 100 according to a representative embodiment is described in connection with FIG. 2. Notably, the present description relates only to an illustrative variation in known fabrication sequences of FBARs and CRFs. Omitted details of the sequence are known, such as described in the referenced patents and patent applications above.

The fabrication of the filter 100 of an embodiment includes forming two structures 201, 202. The structures 201, 202 are in essence the components/materials of CRFs, and are fabricated accordingly. However, after the fabrication of the electrodes 104, 111, an etch-stop layer 203 is provided over the electrode 104. Thereafter, the sequence continues until all layers are provided and features defined. Next, a masking step is effected to form a mask 204 over the structure 202; and a selective etch (wet or dry) is carried out to remove the layers of the stack 201 down to the etch-stop layer 203. After removal of the etch-stop 203 and the mask 204, the FBAR filter section 101 and the CRF section section 102 remain. Connections are then made between the filter sections 101, section 102 with the resultant filter 100. As will be appreciated, the added fabrication sequence is carried in large scale processing providing a multiplicity of filters 100.

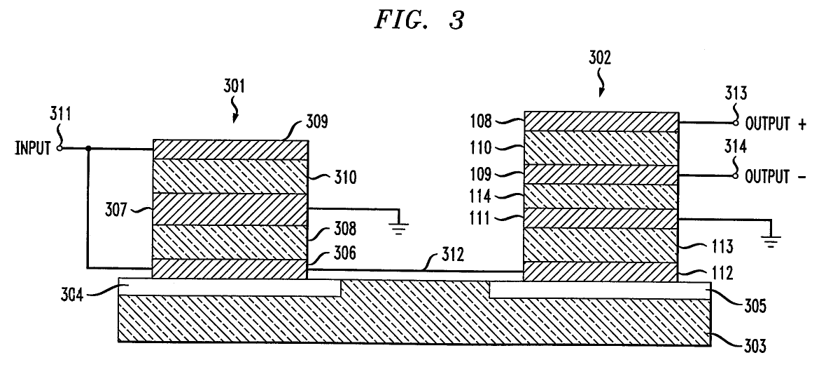

FIG. 3 is a cross-sectional view of a hybrid acoustic resonator filter 300 in accordance with a representative embodiment. The hybrid acoustic resonator filter 300 includes many of the features and details of the filter 100 described previously. Such common features are generally not repeated in order to avoid obscuring the description of the present embodiment.

The filter includes a stacked bulk acoustic resonator (SBAR) filter section 301 and a CRF 302 disposed over the common substrate 303. As before, filter sections 301, 302 are formed over either a cavity or a reflector, shown generically as 304, 305. The SBAR filter section 301 comprises a known electrically coupled acoustic filter section. For example, the SBAR filter section 301 may be as described in commonly-owned U.S. Pat. Nos. 6,384,697 and 5,587,620 to Ruby, et al. The disclosure of these patents are specifically herein incorporated by reference.

The SBAR filter section 301 comprises a lower electrode 306, an intermediate electrode 307 and a first layer of piezoelectric material 308 therebetween. An upper electrode 309 is disposed over a second layer 310 of piezoelectric material. In the present embodiment, the intermediate electrode 307 is connected to ground, and an input 311 is connected to the upper and lower electrodes 309, 306 as shown.

The SBAR filter section 301 also includes an output 312, which connects the SBAR filter section 301 to the CRF 302 via lower electrode 112. The CRF 302 provides a differential output, with a positive output 313, and a negative output 314. The upper electrode 111 is maintained at ground as shown. Accordingly, a single-ended signal is input at the SBAR filter section 301 and is transformed to a differential signal at the output of the CRF 302. Naturally, input of a differential signal to the ‘outputs’ 313, 314 provides a filtered single-ended output signal at the ‘input’ 311.

The SBAR filter section 301 provides a desired passband and nearband rejection to a single-ended signal provided at the input 311. Notably, the selection of the passband and degree of rolloff of the nearband rejection curve can be tailored by proper tuning of the FBARs comprising the SBAR filter section 301. It is contemplated that more than one SBAR (i.e., multistage SBAR) connected in series may be used to more effectively tune the passband and nearband rejection rolloff of the hybrid acoustic resonator filter 300. Thus, the input 311 may be the terminus of such a multi-stage SBAR filter section.

In the present topology, the SBAR filter section 301 comprises two FBARs in electrically connected in parallel and also strongly acoustically coupled in the absence of a decoupling layer. This provides certain benefits of function and fabrication of the hybrid acoustic resonator filter.

For example, by connecting the FBARs in parallel as shown in FIG. 3, the acoustic signals generated in the piezoelectric layers 308, 310 effect a reversal in polarity of the signal between upper electrode 309 and lower electrode 306. This reversal in polarity serves to substantially cancel second harmonic (H₂) signals. As is known, suppression of second harmonics provides certain benefits, particularly compliance with regulatory mandates. Accordingly, second harmonic generation is curbed naturally by the topology of the SBAR filter section 301 of the present embodiments.

Moreover, because the FBARs of the SBAR filter section 301 are connected in parallel, their capacitances add. By comparison to stand-alone FBARs, the SBAR filter section 301 requires one-half the area of the substrate 303 for the same filtering function. As will be appreciated, this results in more efficient use of valuable substrate ‘real estate,’ which in turn results in reduced device size. Beneficially, the same performance as two individual FBARs can be attained in approximately one-half the area.

Fabrication of the hybrid acoustic resonator filter 300 is described briefly to emphasize certain variations in processing that provides both the resultant filter and certain benefits to the resultant filter. The lower electrodes 306, 112, the piezoelectric layers 308, 113 and the upper electrodes 307, 111 are formed by a known sequence such as described above. Moreover, the cavities/reflectors 304, 305 are formed, providing, in essence two FBARs. Next, and prior to further processing, these FBARs are tuned to the desired resonance frequency. Beneficially, by tuning the lower FBARs before further processing, the present sequence fosters accurate tuning of the FBARs.

After the lower FBARs are tuned, a mask is provided over the intermediate electrode 307 and the acoustic decoupling layer 114 is formed. The mask is removed and the piezoelectric layers 310, 110 and the upper electrodes 309, 313 are formed. Thereafter, the tuning of the ‘upper’ FBARs comprising, respectively, the intermediate electrode 307, layer 310 and upper electrode 309; and lower electrode 109, layer 110 and upper electrode 108, is carried out. A passivation layer may then be formed over the hybrid acoustic resonator filter 300 to avoid contamination and attendant frequency drift.

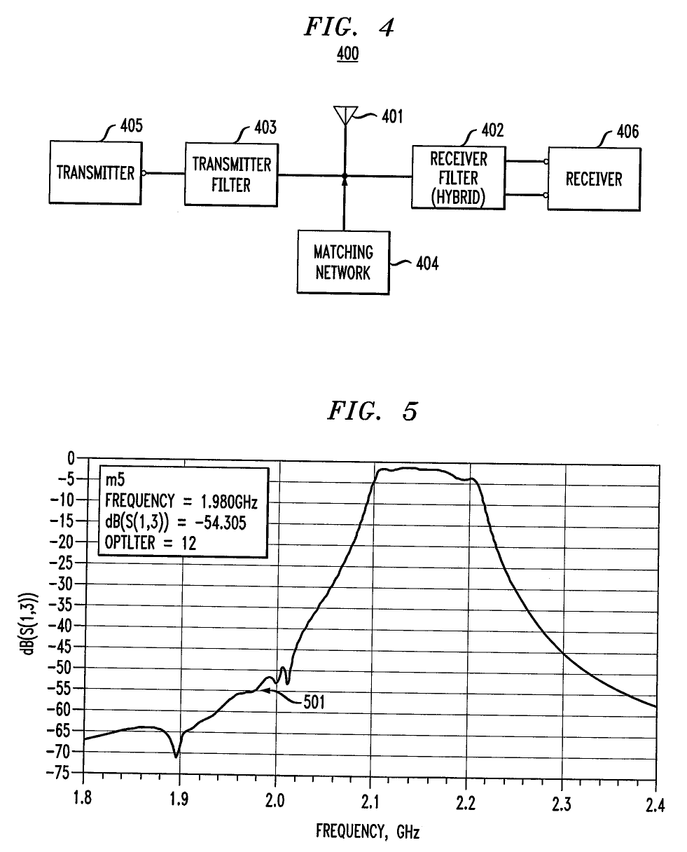

FIG. 4 is a simplified schematic block diagram of a communication device 400 in accordance with a representative embodiment. The communication device 400 may be, for example, a cellular phone or similar device adapted for full duplex communication. The device 400 includes an antenna 401, which is connected to a receiver filter 402 and a transmitter filter 403. An impedance matching network 404 is provided to facilitate the duplex function to and from the antenna 401. This impedance matching network 404 can be representative of impedance matching provided by the CRF topology. Illustratively, the CRF section can provide, besides the single-ended to differential transformation, an impedance transformation. The impedance transformation can be realized by a stack imbalance and thus different thicknesses of the piezoelectric material of the top FBAR in comparison to the bottom FBAR. In particular, and as described in the referenced commonly owned U.S. Patent Publication 2007/0176710 to Jamneala, et al, the impedance transformation ratio is equal to the ratio of the thicknesses of the two piezoelectric layers of the FBARs of the CRF stack. Alternatively, the impedance transformation can be realized changing the electrode material, or the piezoelectric material, or both, such that the optimum piezoelectric thickness required for each FBAR in the CRF is different. Still alternatively, other known matching techniques/networks may be used.

The transmitter filter 403 connects the antenna to a transmitter 405 and includes a single-ended filter section having a passband selected to correspond to the passband of the transmitter of the communication device 400. The transmitter filter 403 may be an acoustic resonator filter section such as an FBAR or multi-stage FBAR, or an SBAR such as described above.

The receiver filter 402 connects the antenna to the receiver 406 and includes a hybrid acoustic resonator filter such as described above. The hybrid acoustic resonator filter provides the desired passband and nearband rejection desired for a single-ended signal in a differential output 407 to the receiver 406. The receiver filter comprises a hybrid acoustic resonator filter 100 or 300 describe previously.

FIG. 5 is a graphical representation of a passband of a known CRF filter. In an embodiment, the filter may be a CRF filter having a single-ended input and differential output. For example, the filter may be an acoustic coupled filter such as a CRF. In the application shown, the near band rejection must be on the order of −60 dB or greater at 1.98 GHZ. Clearly, as shown at point 501 of the graph, the known filter provides insufficient nearband roll-off/rejection of approximately −55 dB.

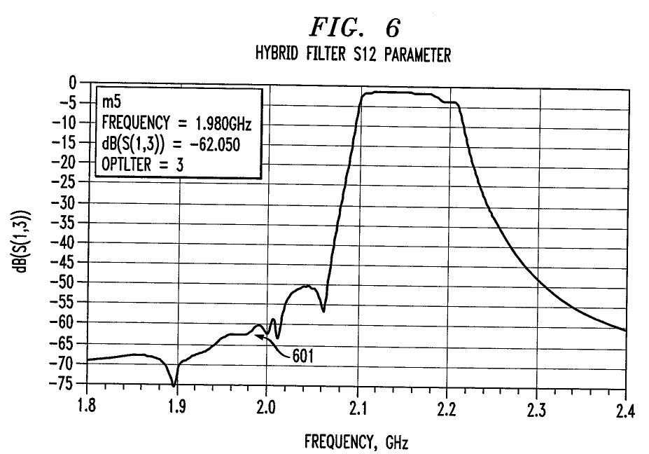

FIG. 6 is a graphical representation of a passband of a hybrid acoustic resonator filter of a representative embodiment. By contrast to the known filter, and as shown at point 601 of the graph, the hybrid acoustic resonator filter provides a nearband rejection of approximately −62.05 dB at 1.98 GHz. As such, a significant improvement in the nearband rejection is realized via the hybrid acoustic resonator filter of the representative embodiments.

In view of this disclosure it is noted that the various hybrid acoustic resonator filters described herein can be implemented in a variety of materials and variant structures. Moreover, applications other than communications filters may benefit from the present teachings. Further, the various materials, structures and parameters are included by way of example only and not in any limiting sense. In view of this disclosure, those skilled in the art can implement the present teachings in determining their own applications and needed materials and equipment to implement these applications, while remaining within the scope of the appended claims.

1. A hybrid acoustic resonator filter adapted for single-ended to differential signal transformation, comprising:
a film bulk acoustic resonator (FBAR) filter section comprising a single-ended output; and
a coupled mode resonator filter (CRF) section comprising an input connected to the single-ended output, and a differential signal output.

2. A hybrid acoustic resonator filter as claimed in claim 1, wherein the FBAR filter section further comprises a first FBAR and a second FBAR in parallel with the first FBAR.

3. A hybrid acoustic resonator filter as claimed in claim 1, wherein the FBAR filter section further comprises a stacked bulk acoustic resonator (SBAR) device.

4. A hybrid acoustic resonator filter as claimed in claim 3, wherein the SBAR further comprises a first FBAR and a second FBAR disposed over the first FBAR, and the first and second FBARs are connected electrically in parallel to provide rejection of second harmonic signals.

5. A hybrid acoustic resonator filter as claimed in claim 1, wherein the CRF further comprises:
a first FBAR and a second FBAR disposed over the first FBAR; and
an acoustic decoupling layer disposed between the first and second FBARs.

6. A communication device, comprising:
a transmitter;
a receiver; and
a hybrid acoustic resonator filter adapted for single-ended to differential signal transformation, the hybrid acoustic resonator filter comprising:
a film bulk acoustic resonator (FBAR) filter section comprising a single-ended output; and
a coupled mode resonator filter (CRF) section comprising an input connected to the single-ended output, and a differential signal output.

7. A communication device as claimed in claim 5, wherein the FBAR filter section further comprises a first FBAR and a second FBAR in parallel with the first FBAR.

8. A communication device as claimed in claim 5, wherein the FBAR filter section further comprises a stacked bulk acoustic resonator (SBAR) device.

9. A communication device as claimed in claim 8, wherein the SBAR further comprises a first FBAR and a second FBAR disposed over the first FBAR, and the first and second FBARs are connected electrically in parallel to provide rejection of second harmonic signals.

10. A communication device as claimed in claim 6, wherein the CRF section further comprises:
a first FBAR and a second FBAR disposed over the first FBAR; and
an acoustic decoupling layer disposed between the first and second FBARs.

11. A communication device as claimed in claim 6, wherein the hybrid acoustic resonator filter is connected to an antenna and the differential signal output is connected to the receiver.

12. A hybrid acoustic resonator filter, comprising:
an electrically coupled film bulk acoustic wave resonator (FBAR) filter section having a single-ended signal output; and
an acoustically coupled film bulk acoustic wave resonator filter section connected to the single-ended signal output and comprising a differential signal output.

13. A hybrid acoustic resonator filter as claimed in claim 12, wherein the FBAR filter section further comprises a ladder FBAR filter.

14. A hybrid acoustic resonator filter as claimed in claim 12, wherein the FBAR filter section further comprises a stacked bulk acoustic resonator (SBAR) device.

15. A communication device, comprising:
a transmitter;
a receiver; and
a hybrid acoustic resonator filter adapted for single-ended to differential signal transformation, the hybrid acoustic resonator filter comprising:
an electrically coupled film bulk acoustic wave resonator (FBAR) filter section having a single-ended signal output; and
an acoustically coupled film bulk acoustic wave resonator filter section connected to the single-ended signal output and comprising a differential signal output.

16. A communication device as claimed in claim 15, wherein the FBAR filter section further comprises a ladder FBAR filter.

17. A communication device as claimed in claim 15, wherein the FBAR filter section further comprises a stacked bulk acoustic resonator (SBAR) device.
